(19) United States
(12) Patent Application Publication
(10) Pub. No.: US 2006/0071314 A1
(43) Pub. Date: Apr. 6, 2006

(54) Cavity-down stacked multi-chip package

(75) Inventors: Kwun-Yao Ho, Taipei Hsien (TW); Moriss Kung, Taipei Hsien (TW)

Correspondence Address: BRUCE H. TROXELL;SUITE 1404, 5205 LEESBURG PIKE, FALLS CHURCH, VA, 22041, US

(73) Assignee: Via Technologies, Inc.

(21) Appl. No.: 11/205,107

(22) Filed: Aug. 17, 2005

(30) Foreign Application Priority Data
Oct. 5, 2004 (TW) 93130128

(51) Int. Cl. H01L 23/02

(52) U.S. Cl. 257/685

(57) ABSTRACT

A cavity-down stacked multi-chip package with a plurality of packages stacked together is provided. The uppermost package has a circuit board with an opening, a heat spreader, and a chip. The heat spreader is positioned on the circuit board and covers the opening. The chip is positioned in the opening and adhered to a lower surface of the heat spreader. In addition, the chip is electrically connected to a lower surface of the circuit board through at least a conductive wire.

### BACKGROUND OF THE INVENTION

(1) Field of the Invention

The present invention relates to a stacked multi-chip package, and more particularly to a cavity-down stacked multi-chip package.

(2) Description of Related Art

As the development of telecommunication network, the demand of portable communication terminals such as mobile phone, personal digital assistant (PDA) is increased. In addition, the improvement of telecommunication technology extends the services provided on the mobile phone, and some popular services, such as music sharing, web friends, on-line games, voice mail delivering and receiving, etc., become available. However, these services usually attend with huge data transmission, which challenge the performance of memories within the mobile phone.

For solving this problem, some advance integrated circuit fabrication technologies need to be used to increase the density of memory cells within the memory chip and reduce the power consumption of the memory chip. However, such technologies always increase the fabrication cost and risk. By contrast, the stacked multi-chip package (ST-MCP) has the advantages of reducing packaging size and power consumption under the present IC fabrication technology. It is understood as an effective and inexpensive method for solving such problem.

FIG. 1 shows a cross-section view of a typical stacked multi-chip package, which is composed of a first package 100 and a second package 200, wherein the second package 200 is stacked on the first package 100 and adhered to the first package 100 by using a thermal conductive layer 320.

The first package 100 includes a first circuit board 120 and a first chip 140. The first chip 140 is mounted on the first circuit board 120 and electrically connected to the circuit patterns on the first circuit board 120 through some conductive wires 160. The first chip 140 and the conductive wires 160 are covered with a packaging material layer 180 for electrical isolation. The second package 200 includes a second circuit board 220 and a second chip 240. The second chip 240 is mounted on the second circuit board 220 and electrically connected to the circuit patterns on the second circuit board 220 through some conductive wires 260. The second chip 240 and the conductive wires 260 are covered with a packaging material layer 280 for electrical isolation.

In order to have the electrical signals exchanged between the first circuit board 120 and the second circuit board 220, the circuit patterns on the first circuit board 120 is electrically connected to the circuit patterns on the second circuit board 220 through some conductive wires 360. Thereby, the second chip 240 is electrically connected to the first circuit board 120, and the electrical signals generated by the second chip 240 can be transmitted outside the stacked multi-chip package through the second circuit board 220 and the first circuit board 120.

The heat generated by the first chip 140 within the first package 100 can be dissipated downward through the first circuit board 120. Whereas, since the second circuit board 220 of the second package 200 is stacked on the first package 100, the heat generated by the second chip 240 is difficult to be dissipated downward through the second circuit board 220. In addition, the packaging material layer 280 covering the second chip 240 is poor in thermal transmission so as to hinder the heat dissipated upward. As a result, the heat is segregated in the second package 200 to decline the operating efficiency of the second chip 240.

Accordingly, as the need of stacked multi-chip package is increased, how to improve the traditional packaging structure to meet the demand of both thermal dissipating efficiency and packaging size, has become an important topic for the packaging technology.

### SUMMARY OF THE INVENTION

A main object of the present invention is to reduce the thickness of the stacked multi-chip package.

A second object of the present invention is to increase the thermal dissipating rate of the stacked multi-chip package.

The stacked multi-chip package provided in the present invention is composed of a plurality of packages stacked together, wherein the uppermost package includes a circuit board with an opening, a heat spreader, and a chip. The heat spreader is stacked on the circuit board and covers the opening of the circuit board. The chip is positioned inside the opening and adhered to a lower surface of the heat spreader. The chip is also electrically connected to the conductive patterns on a lower surface of the circuit board through at least a first conductive wire.

Reference will now be made in detail to the preferred embodiments of the present invention, examples of which are illustrated in the accompanying drawings. Wherever possible, the same reference numbers will be used throughout the drawings to refer to the same or like parts.

### BRIEF DESCRIPTION OF THE DRAWINGS

The present invention will now be specified with reference to its preferred embodiment illustrated in the drawings, in which:

FIG. 1 shows a cross-section view depicting a typical stacked multi-chip package;

FIG. 2 shows a cross-section view depicting a first preferred embodiment of the stacked multi-chip package in accordance with the present invention;

FIG. 3 shows a cross-section view depicting a second preferred embodiment of the stacked multi-chip package in accordance with the present invention;

FIG. 4 shows a cross-section view depicting a third preferred embodiment of the stacked multi-chip package in accordance with the present invention; and

FIG. 5 shows a block diagram depicting a preferred embodiment of an electronic system in accordance with the present invention.

### DETAIL DESCRIPTION OF THE PREFERRED EMBODIMENTS

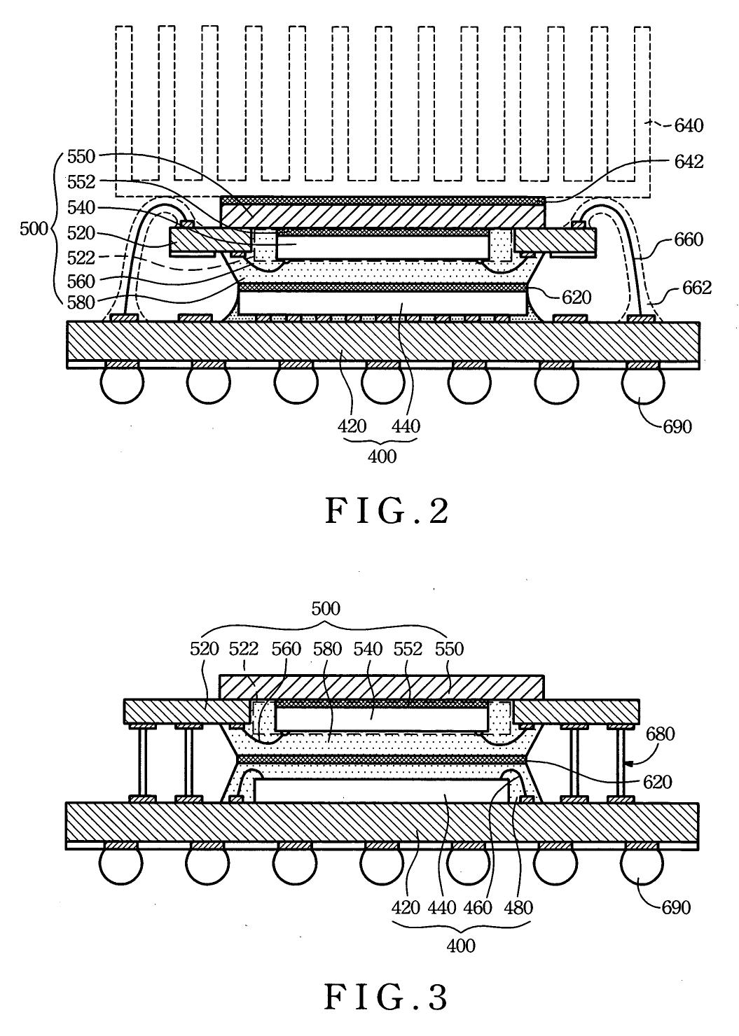

FIG. 2 shows a cross-section view of a first preferred embodiment of a stacked multi-chip package in accordance with the present invention. The stacked multi-chip package includes a first package 400 and a second package 500. The first package 400 has a first circuit board 420 and a first chip 440. The first chip 440 is mounted on an upper surface of the first circuit board 420 and flip-chip packaged on the first circuit board 420. The second package 500 is stacked on the first package 400. A thermal conductive layer 620 is interposed between the first package 400 and the second package 500 so as to have the second package 500 adhered to the first package 400.

The second package 500 includes a second circuit board 520 with an opening 522 inside, a heat spreader 550, and a second chip 540. The heat spreader 550 is positioned on the second circuit board 520 and covers the opening 522. The second chip 540 is positioned in the opening 522 and adhered to a lower surface of the heat spreader 550 through a thermal conductive layer 552. At least a first conductive wire 560 is connected between a lower surface of the second chip 540 and a lower surface of the second circuit board 520 for transmitting the electrical signals between the second chip 540 and the second circuit board 520. Moreover, an isolation layer 580 is filled into the opening 522 and covers the second chip 540 and the first conductive wire 560 so as to electrically isolate the first conductive wire 560 from the environment. In addition, the isolation layer 580 also prevents the contact between the first conductive wire 560 and the second chip 540 as well as the contact between the first conductive wire 560 and the second circuit board 520 from being cracked.

A plurality of second conductive wires 660 is connected between an upper surface of the first circuit board 420 and an upper surface of the second circuit board 520. The electrical signals generated by the second chip 540 may be transmitted to the first circuit board 420 through the second circuit board 520 and the second conductive wires 660. The electrical signals may further output to a main board (not shown) crossing the conductive balls 690 formed on a lower surface of the first circuit board 420. In order to provide proper electrical isolation, an isolation layer 662 is used to cover the second conductive wires 660. The isolation layer 662 also covers the contacts between the second conductive wires 660 and the first circuit board 420 as well as the contacts between the second conductive wires 660 and the second circuit board 520 to prevent the contacts from being cracked.

In the present embodiment, the heat generated by the operation of the first chip 440 can be efficiently dissipated downward through the first circuit board 420. In addition, the heat generated by the operation of the second chip 540 can be dissipated upward to the heat spreader 550. The heat spreader 550, which is mainly composed of high thermal conductivity material, has better heat transfer efficiency with respect to the circuit boards 420, 520, so as to remove the heat and cool down the second chip 540 effectively. Since the surface area between the heat spreader 550 and the ambient air determines the heat transfer efficiency, a fin structure 640 may be adhered on an upper surface of the heat spreader 550 by using a thermal conductive layer 642 to increase the total heat transfer surface area. In some cases, the fin structure 640 may be integrated with the heat spreader 550 as a single unit (not shown).

Although the mentioned embodiment only depicts the case with two packages stacked together, the present invention is applicable to the stacked multi-chip package with more than two packages. In such cases, the uppermost package specifies a cavity-down design as the second package shown in FIG. 2 with an opening 522 to have the chip 540 adhered to the lower surface of the heat spreader 550 directly.

FIG. 3 shows a cross-section view of second preferred embodiment of the stacked multi-chip package in the present invention. The stacked multi-chip package includes a first package 400 and a second package 500. The first package 400 includes a first circuit board 420 and a first chip 440. The first chip 440 is mounted on the first circuit board 420 and electrically connected to the first circuit board 420 through a plurality of conductive wires 460, that is, the first chip 440 is wire-bonded packaged on the first circuit board 420. An isolation layer 480 covers the first chip 440 and the conductive wires 460 for providing proper mechanical, electrically, and chemical protections.

The second package 500 is stacked on the first package 400 and adhered to an upper surface of the isolation layer 480 by using a thermal conductive layer 620. The second package 500 includes a second circuit board 520 with an opening 522 inside, a heat spreader 550, and a second chip 540. The heat spreader 550 is stacked on the second circuit board 520 and covers the opening 522. The second chip 540 is positioned in the opening 522 and adhered to a lower surface of the heat spreader 550. At least a first conductive wire 560 is connected between a lower surface of the second chip 540 and the lower surface of the second circuit board 520 so as to have the electrical signals transmitted between the second chip 540 and the second circuit board 520. Moreover, an isolation layer 580 is filled into the opening 522 and covers the second chip 540 and the first conductive wire 560 so as to electrically isolate the first conductive wire 560 from the environment. In addition, the isolation layer 580 also prevents the contact between the first conductive wire 560 and the second chip 540 as well as the contact between the first conductive wire 560 and the second circuit board 520 from being broken.

A plurality of pins 680 (or conductive posts) is arrayed on the lower surface of the second circuit board 520. The pins 680 (or conductive posts) are extended downward to attach an upper surface of the first circuit board 420 so as to build some electrical signal transmitting paths between the first circuit board 420 and the second circuit board 520. Thereby, the electrical signals generated by the second chip 540 can be transmitted to the first circuit board 420 through the second circuit board 520 and the pins 680 (or conductive post), and further output to a main board (not shown) through the conductive balls 690 formed on a lower surface of the first circuit board 420.

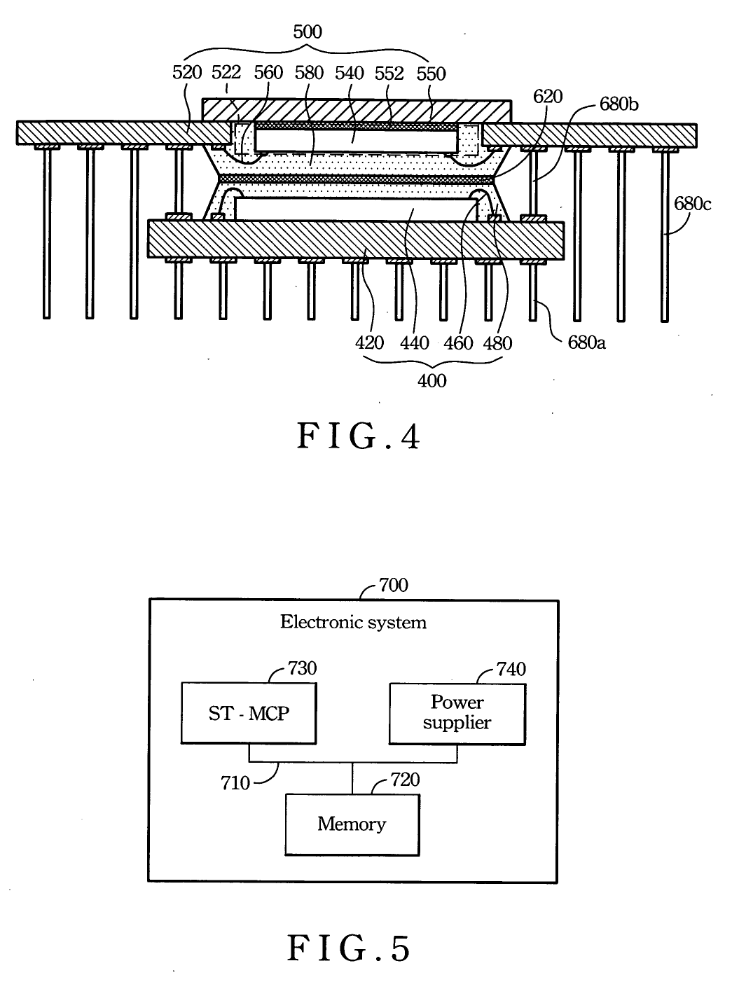

FIG. 4 shows a cross-section view of third preferred embodiment of the stacked multi-chip package in accordance with the present invention. The stacked multi-chip package includes a first package 400 and a second package 500. The first package 400 includes a first circuit board 420 and a first chip 440. The first chip 440 is mounted on the first circuit board 420 and electrically connected to the first circuit board 420 by using a plurality of conductive wires 460. An isolation layer 480 covers the first chip 440 and the conductive wires 460 for providing proper mechanical, electrically, and chemical protections.

The second package 500 is stacked on the first package 400 and adhered to an upper surface of the isolation layer 480 by using a thermal conductive layer 620. The second package 500 includes a second circuit board 520, a heat spreader 550, and a second chip 540. The second circuit board 520 has an opening 522. The heat spreader 550 is stacked on the second circuit board 520 and covers the opening 522. The second chip 540 is positioned in the opening 522 and adhered to a lower surface of the heat spreader 550. At least a first conductive wire 560 is connected between the lower surface of the second chip 540 and the lower surface of second circuit board 520 so as to have the electrical signals transmitted between the second chip 540 and the second circuit board 520. An isolation layer 580 is filled into the opening 522 and covers the second chip 540 and the first conductive wire 560 so as to provide proper electrically isolation and prevent the contact between the first conductive wire 560 and the second chip 540 as well as the contact between the first conductive wire 560 and the second circuit board 520 from being cracked.

A plurality of pins 680a is formed on a lower surface of the first circuit board 420 for plugging into the respected holes on the main board (not shown). It should be also noted that the surface area of the lower surface of the second circuit board 520 is greater than that of the upper surface of the first circuit board 420. That is, the edges of the second circuit board 520 extend to the outside of the first circuit board 420. Therefore, only part of the pins 680b formed on the lower surface of the second circuit board 520 attach to the upper surface of the first circuit board 420. The other pins 680c are extended to below the first circuit board 420 for plugging into the holes on the main board (not shown).

FIG. 5 shows a preferred embodiment of an electronic system in accordance with the present invention. The electronic system 700 includes a bus 710, a memory 720, a stacked multi-chip package 730 as shown in FIG. 2, and a power supplier 740. The memory 720, the stacked multi-chip package 730, and the power supplier 740 are communicated with each other through the bus 710. As shown in FIG. 2, the stacked multi-chip package 730 includes a first package 400 and a second package 500. The first package 400 includes a first circuit board 420 and a first chip 440. The first chip 440 is mounted on the first circuit board 420 and electrically connected to the bus 710 through the first circuit board 420. The second package 500 stacked on the first package 400 includes a second circuit board 520 with an opening 522, a heat spreader 550, and a second chip 540. The electrical signals generated by the second chip 540 are transmitted to the bus 710 through the first conductive wires 560, the second circuit board 520, the second conductive wires 660, and the first circuit board 420.

The first chip 440 and the second chip 540 of the stacked multi-chip package 730 in accordance with the present invention may be a system chip, a central processing unit chip, or a memory chip. In addition, the electrical signals can be transmitted between the first chip 440 and the second chip 540 without leaving the package 730 to achieve the object of system on package (SOP) design.

By contrast to the traditional stacked multi-chip package, the stacked multi-chip package provided in the present invention has the following advantages:

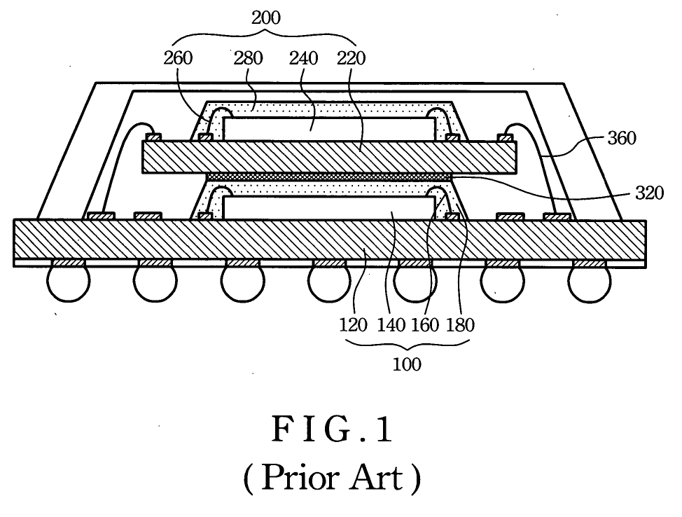

1. As shown in FIG. 1, the second chip 240 of the traditional multi-chip package is covered with the packaging material layer 280, which is poor in thermal transmission. In addition, the heat generated by the second chip 240 cannot be effectively dissipated downward through the second circuit board 220, for the first package 100 is stacked below the second package 200. Whereas, as shown in FIG. 2, in the stacked multi-chip package of the present invention, the second chip 540 is adhered to the heat spreader 550 so as to have the heat dissipated upward effectively. Therefore, the second chip 540 of the stacked multi-chip package in the present invention can be effectively cool down to promote the operation efficiency.

2. As shown in FIG. 1, the conductive wires 360 of the traditional stacked multi-chip package connected to the upper surface of the second circuit board 220 restricts the layout of the conductive patterns on the upper surface of the second circuit board 220, especially the arrangement of test pads as well as the packaging testing process. Whereas, as shown in FIG. 3, since the second circuit board 520 in accordance with the present invention is electrically connected to the first circuit board 420 through the pins 680 arrayed on the lower surface of the second circuit board 520, the upper surface of the second circuit board 520 has greater space to arrange test pads to facilitate packaging testing process.

With the example and explanations above, the features and spirits of the invention will be hopefully well described. Those skilled in the art will readily observe that numerous modifications and alterations of the device may be made when retaining the teaching of the invention. Accordingly, the appended claims are intended to cover all embodiments without departing from the spirit and scope of the present invention.

What is claimed is:

1. A stacked multi-chip package comprising:
a first package having:
a first circuit board; and
at least a first chip mounted an upper surface of the first circuit board and electrically connected thereto,
a plurality of first electrical connecting structures positioned on a lower surface of the first circuit board;
a second package stacked on the first package having:
a second circuit board with an opening;
a heat spreader positioned on an upper surface of the second circuit board and covering the opening; and
at least a second chip positioned in the opening, adhered to a lower surface of the heat spreader, and electrically connected to a lower surface of the second circuit board through at least a first conductive wire;
a plurality of second electrical connecting structures electrically connecting the first circuit board and the second circuit board.

2. The stacked multi-chip package according to claim 1 wherein the second circuit package further having an isolation layer filling the opening and covering the second chip and the first conductive wires.

3. The stacked multi-chip package according to claim 1 wherein the second electrical connecting structure is a second conductive wire.

4. The stacked multi-chip package according to claim 3 wherein the second conductive wires are connected to an upper surface of the second circuit board and the upper surface of the first circuit board.

5. The stacked multi-chip package according to claim 1 wherein the second electrically connecting structures are pins or conductive posts.

6. The stacked multi-chip package according to claim 5 wherein part of the pins or conductive posts are connected to the upper surface of the first circuit board and the lower surface of the second circuit board.

7. The stacked multi-chip package according to claim 5 wherein the surface area of the lower surface of the second circuit board is larger than that of the upper surface of the first circuit board, and further comprising a plurality of pins or conductive posts adhered to the lower surface of the second circuit board extending to below the first circuit board.

8. The stacked multi-chip package according to claim 1 wherein the first chip is flip-chip or wire-bonded packaged on the first circuit board.

9. The stacked multi-chip package according to claim 1 wherein the first electrically connecting structures are pins, conductive posts, or solder balls.

10. The stacked multi-chip package according to claim 1 further comprising a thermal conductive layer interposed between the first package and the second package.

11. A stacked multi-chip package composed of a plurality of packages stacked together, wherein the uppermost package comprising:
a circuit board with an opening;
a heat spreader positioned on an upper surface of the circuit board and covering the opening; and
at least a chip positioned in the opening, adhered to a lower surface of the heat spreader, and electrically connected to a lower surface of the circuit board through at least a first conductive wire;
wherein the circuit board is electrically connected to the other packages through a plurality of electrically connecting structures.

12. The stacked multi-chip package according to claim 11 wherein the uppermost package further comprising an isolation layer filling the opening and covering the chip and the first conductive wires.

13. The stacked multi-chip package according to claim 11 wherein the electrically connecting structure is a second conductive wire.

14. The stacked multi-chip package according to claim 13 wherein the second conductive wires are connected to an upper surface of the circuit board.

15. The stacked multi-chip package according to claim 11 wherein the electrically connecting structure are pins or conductive posts arrayed on a lower surface of the circuit board.

16. The stacked multi-chip package according to claim 15 wherein part of the pins or the conductive posts are connected to the circuit board of the other packages.

17. The stacked multi-chip package according to claim 15 wherein part of the pins or the conductive posts are extended to below the stacked multi-chip package.

18. An electronic system formed on a printed circuit board, the electronic system comprising:
a bus;
a memory connecting to the bus;
a stacked multi-chip package including a first package and a second package stacked on the first package, wherein the second package having:
a circuit board with an opening;
a heat spreader positioned on an upper surface of the circuit board and covering the opening; and
a chip positioned in the opening, adhered to a lower surface of the heat spreader, and electrically connected to a lower surface of the circuit board through at least a conductive wire;
wherein the circuit board electrically connected to the first package through a plurality of electrically connecting structures.

19. The electronic system according to claim 18 wherein the first package is a flip-chip package or a wire-bonded package.

20. The electronic system according to claim 18 wherein the second package is adhered to the first package through a thermal conductive layer.

21. The electronic system according to claim 18 wherein the chip within the second package is a microprocessor or a memory chip.
